(19) United States
(12) Patent Application Publication
(10) Pub. No.: US 2026/0293155 A1
(43) Pub. Date: Sep. 24, 2026

(54) MAGNETORESISTANCE EFFECT ELEMENT AND MAGNETIC MEMORY

(71) Applicant: TDK CORPORATION, Tokyo (JP)

(72) Inventors: Shuji OKAME, Tokyo (JP); Katsuyuki NAKADA, Tokyo (JP)

(73) Assignee: TDK CORPORATION, Tokyo (JP)

(21) Appl. No.: 19/084,070

(22) Filed: Mar. 19, 2025

(51) Int. Cl. H10B 61/00

(52) U.S. Cl. CPC H10B 61/20

(57) ABSTRACT

This magnetoresistance effect element includes a laminate, a first wiring, and a second wiring. The laminate includes a spin-orbit torque wiring, a first ferromagnetic layer, a nonmagnetic layer, and a second ferromagnetic layer. A side surface of the laminate is a continuous inclined surface. The first ferromagnetic layer is between the spin-orbit torque wiring and the nonmagnetic layer in a lamination direction of the laminate. The nonmagnetic layer is between the first ferromagnetic layer and the second ferromagnetic layer in the lamination. The first wiring is connected to the spin-orbit torque wiring. The second wiring is connected to the spin-orbit torque wiring at a position different from that of the first wiring in a first direction. A first end surface of the first wiring on a side close to the spin-orbit torque wiring is inward of a first end of the spin-orbit torque wiring in the first direction.

### TECHNICAL FIELD

The present disclosure relates to a magnetoresistance effect element and a magnetic memory.

### BACKGROUND ART

A giant magnetoresistance (GMR) element formed of a multilayer film including a ferromagnetic layer and a nonmagnetic layer, and a tunnel magnetoresistance (TMR) element in which an insulating layer (a tunnel barrier layer, a barrier layer) is used as a nonmagnetic layer are known as a magnetoresistance effect element. Magnetoresistance effect elements can be applied to magnetic sensors, high-frequency components, magnetic heads, and magnetic random-access memories (MRAM).

An MRAM is a storage element in which magnetoresistance effect elements are integrated. In an MRAM, data is read and written by utilizing characteristics in which a resistance of a magnetoresistance effect element changes when directions of magnetization of two ferromagnetic layers sandwiching a nonmagnetic layer in the magnetoresistance effect element change. A magnetization direction of the ferromagnetic layer is controlled by utilizing, for example, a magnetic field generated by a current. Also, for example, the magnetization direction of the ferromagnetic layer is controlled by utilizing a spin transfer torque (STT) generated when a current is caused to flow in a lamination direction of the magnetoresistance effect element.

When a magnetization direction of the ferromagnetic layer is rewritten by utilizing the STT, a current flows in a lamination direction of the magnetoresistance effect element. A write current causes deterioration in characteristics of the magnetoresistance effect element.

In recent years, attention has been focused on a method that does not require a current to be caused to flow in a lamination direction of the magnetoresistance effect element during writing (for example, Patent Document 1). One of the methods is a write method utilizing a spin-orbit torque (SOT). An SOT is induced by a spin current generated by a spin-orbit interaction or by the Rashba effect at an interface between different materials. A current for inducing the SOT in a magnetoresistance effect element flows in a direction intersecting a lamination direction of the magnetoresistance effect element. That is, magnetization rotation using the SOT does not require a current to flow in a lamination direction of the magnetoresistance effect element, and thus a prolonged life of the magnetoresistance effect element is expected. Patent Document 1 discloses a method of collectively forming magnetoresistance effect elements to increase an integration density of a magnetic memory.

### CITATION LIST

### Patent Document

Patent Document 1: Japanese Patent No. 6610839

### SUMMARY

### Technical Problem

A spin-orbit torque is induced by causing a current to flow through a spin-orbit torque wiring and injecting spins from the spin-orbit torque wiring into the ferromagnetic layer. When a current is caused to flow through the spin-orbit torque wiring, concentration of current is likely to occur in the vicinity of an edge or interface. If a laminate including a spin-orbit torque wiring is collectively formed, when a current is concentrated and flows along a side surface of the laminate, migration of elements constituting the laminate may occur. Migration of elements is one of causes of a decrease in MR ratio of the magnetoresistance effect element.

The present disclosure has been made in view of the above circumstances, and an objective of the present invention is to provide a magnetoresistance effect element and a magnetic memory capable of suppressing localized current concentration.

### Solution to Problem

In order to solve the above-described problems, the present disclosure provides the following means.

A magnetoresistance effect element according to one aspect includes a laminate, a first wiring, and a second wiring. The laminate includes a spin-orbit torque wiring, a first ferromagnetic layer, a nonmagnetic layer, and a second ferromagnetic layer. A side surface of the laminate is a continuous inclined surface. The first ferromagnetic layer is between the spin-orbit torque wiring and the nonmagnetic layer in a lamination direction of the laminate. The nonmagnetic layer is between the first ferromagnetic layer and the second ferromagnetic layer in the lamination direction of the laminate. The first wiring is connected to the spin-orbit torque wiring. The second wiring is connected to the spin-orbit torque wiring at a position different from that of the first wiring in a first direction. A first end surface of the first wiring on a side close to the spin-orbit torque wiring is inward of a first end of the spin-orbit torque wiring in the first direction.

### Effects of Invention

The magnetoresistance effect element and the magnetic memory according to the present disclosure can suppress localized current concentration.

### BRIEF DESCRIPTION OF DRAWINGS

FIG. 1 A circuit schematic diagram of a magnetic memory according to a first embodiment.

FIG. 2 A cross-sectional view of a characteristic portion of the magnetic memory according to the first embodiment.

FIG. 3 A cross-sectional view of a magnetoresistance effect element according to the first embodiment.

FIG. 4 A plan view of the magnetoresistance effect element according to the first embodiment.

FIG. 5 A cross-sectional view of a magnetoresistance effect element according to a second embodiment.

FIG. 6 A cross-sectional view of a magnetoresistance effect element according to a third embodiment.

FIG. 7 A cross-sectional view of a magnetoresistance effect element according to a fourth embodiment.

FIG. 8 is a cross-sectional view of a magnetoresistance effect element according to a fifth embodiment.

FIG. 9 A cross-sectional view of a magnetoresistance effect element according to a sixth embodiment.

FIG. 10 A cross-sectional view of a magnetoresistance effect element according to a seventh embodiment.

FIG. 11 A cross-sectional view of a magnetoresistance effect element according to an eighth embodiment.

FIG. 12 A cross-sectional view of a magnetoresistance effect element according to a ninth embodiment.

FIG. 13 A cross-sectional view of a magnetoresistance effect element according to a tenth embodiment.

### DESCRIPTION OF EMBODIMENTS

Hereinafter, the present embodiment will be described in detail with reference to the drawings as appropriate. In the drawings used in the following description, there are cases in which characteristic portions are enlarged for convenience of illustration so that characteristics can be easily understood, and dimensional proportions or the like of components may be different from actual ones. Materials, dimensions, and the like illustrated in the following description are merely examples, and the present disclosure is not limited thereto and can be implemented with appropriate modifications within a range in which the effects of the present disclosure are achieved.

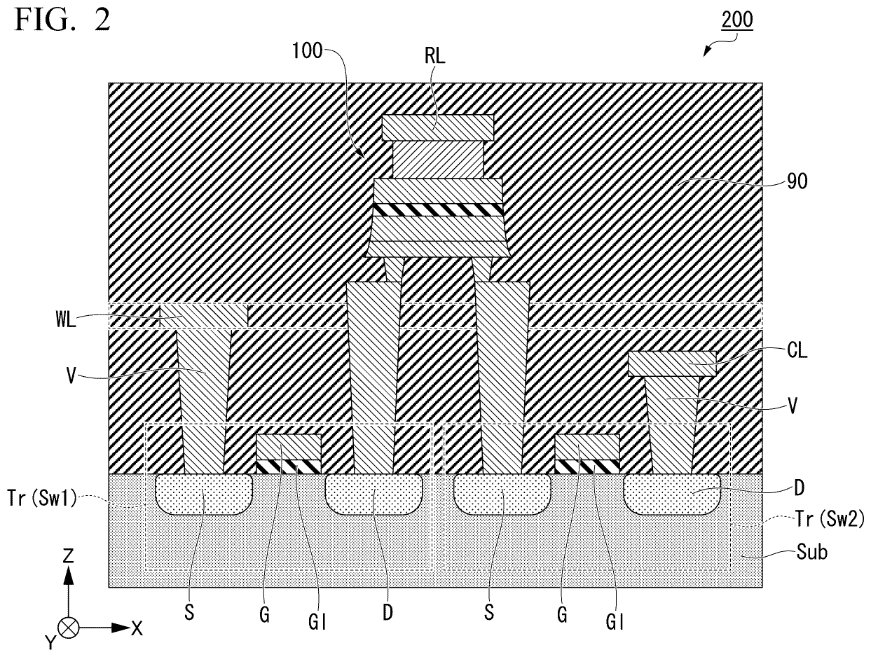

First, directions will be defined. One direction of one surface of a substrate Sub (see FIG. 2) to be described later is defined as an X direction, and a direction orthogonal to the X direction is defined as a Y direction. The X direction is, for example, a direction along a line connecting a first wiring and a second wiring at a shortest distance. A Z direction is a direction orthogonal to the X direction and the Y direction. The Z direction is an example of a lamination direction in which each layer is laminated. Hereinafter, a direction from the substrate Sub toward the magnetoresistance effect element will be referred to as the +Z direction, and may be expressed as “upward”. Also, a direction opposite to the +Z direction (−Z direction) may be expressed as “downward”. “Upward” and “downward” may not necessarily coincide with a direction in which gravity is applied.

In the present specification, “extending in the X direction” means that, for example, a dimension in the X direction is larger than a minimum dimension of dimensions in the X direction, the Y direction, and the Z direction. The same applies to cases of extending in other directions. Also, in the present specification, “inward” refers to a direction toward a center of the magnetoresistance effect element, and it can be said that the closer to the center of the magnetoresistance effect element in an XY plane, the further inward. Also, in the present specification, “outward” refers to a direction away from the center of the magnetoresistance effect element, and it can be said that the further from the center of the magnetoresistance effect element in the XY plane, the further outward.

### First Embodiment

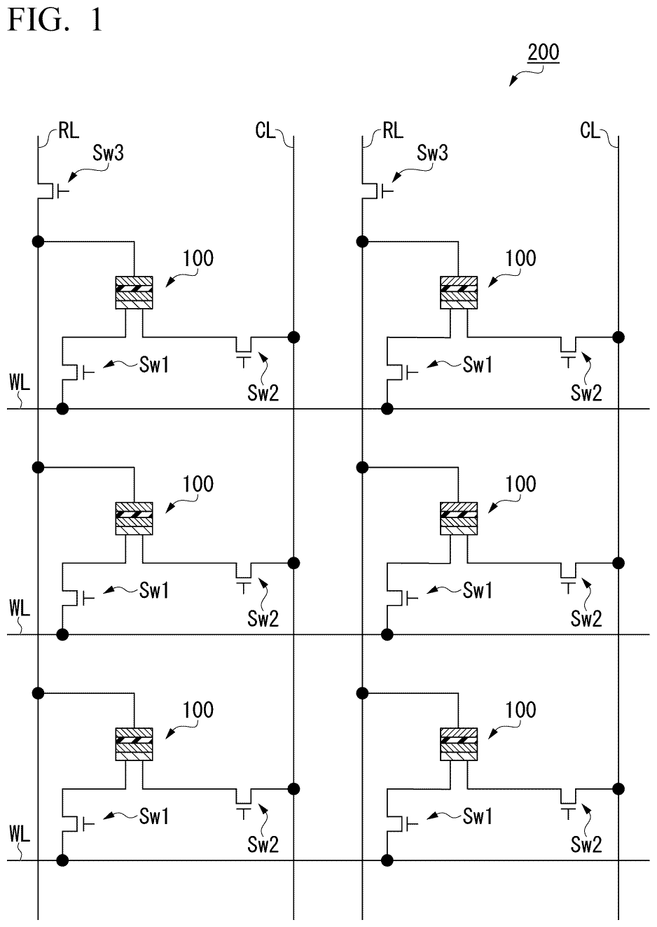

FIG. 1 is a configuration diagram of a magnetic memory 200 according to a first embodiment. The magnetic memory 200 includes a plurality of magnetoresistance effect elements 100, a plurality of write lines WL, a plurality of common lines CL, a plurality of read lines RL, a plurality of first switching elements Sw1, a plurality of second switching elements Sw2, and a plurality of third switching elements Sw3. In the magnetic memory 200, for example, the magnetoresistance effect elements 100 are disposed in a matrix pattern.

Each of the write lines WL electrically connects a power supply and one or more magnetoresistance effect elements 100. Each of the common lines CL is a wiring used at both the time of writing and reading data. Each of the common lines CL electrically connects a reference potential and one or more magnetoresistance effect elements 100. The reference potential is, for example, the ground. The common line CL may be provided in each of the plurality of magnetoresistance effect elements 100, or may be provided across the plurality of magnetoresistance effect elements 100. Each of the read lines RL electrically connects the power supply and one or more magnetoresistance effect elements 100. The power supply is connected to the magnetic memory 200 at the time of use.

Each magnetoresistance effect element 100 is connected to the first switching element Sw1, the second switching element Sw2, and the third switching element Sw3. The first switching element Sw1 is connected between the magnetoresistance effect element 100 and the write line WL. The second switching element Sw2 is connected between the magnetoresistance effect element 100 and the common line CL. The third switching element Sw3 is connected to the read line RL extending across the plurality of magnetoresistance effect elements 100.

When predetermined first and second switching elements Sw1 and Sw2 are turned on, a write current flows between the write line WL and the common line CL which are connected to a predetermined magnetoresistance effect element 100. Due to the flow of the write current, data is written to the predetermined magnetoresistance effect element 100. When predetermined second and third switching elements Sw2 and Sw3 are turned on, a read current flows between the common line CL and the read line RL which are connected to the predetermined magnetoresistance effect element 100. Due to the flow of the read current, data is read from the predetermined magnetoresistance effect element 100.

The first switching element Sw1, the second switching element Sw2, and the third switching element Sw3 are elements that control a flow of a current. The first switching element Sw1, the second switching element Sw2, and the third switching element Sw3 are, for example, transistors. The first switching element Sw1, the second switching element Sw2, and the third switching element Sw3 may be elements utilizing a change in phase of a crystal layer such as ovonic threshold switches (OTS), elements utilizing a change in band structure such as metal-insulator transition (MIT) switches, elements utilizing a breakdown voltage such as Zener diodes and avalanche diodes, or elements whose conductivities change as an atomic position changes.

The third switching element Sw3 of the magnetic memory 200 illustrated in FIG. 1 is shared by the magnetoresistance effect elements 100 connected to the same read line RL. The third switching element Sw3 may be provided in each of the magnetoresistance effect elements 100. Also, the third switching element Sw3 may be provided in each of the magnetoresistance effect elements 100, and the first switching element Sw1 or the second switching element Sw2 may be shared by the magnetoresistance effect elements 100 connected to the same wiring.

FIG. 2 is a cross-sectional view of a characteristic portion of the magnetic memory 200 according to the first embodiment. FIG. 2 is a cross section taken along an XZ plane passing through a center of the magnetoresistance effect element 100 in the Y direction.

The first switching element Sw1 and the second switching element Sw2 illustrated in FIG. 2 are transistors Tr. The third switching element Sw3 is electrically connected to the read line RL, and is positioned, for example, at a different position in the Y direction in FIG. 2. The transistor Tr is, for example, a field effect transistor, and includes a gate electrode G, a gate insulating film GI, and a source S, and a drain D. The source S and the drain D are defined by a direction of a current flow, and a positional relationship between the source S and the drain D may be reversed. The substrate Sub is, for example, a semiconductor substrate.

The transistor Tr is connected to the write line WL or the common line CL by a via wiring V. The via wiring V extends in, for example, the Z direction. The read line RL is connected to the magnetoresistance effect elements 100. The via wiring V contains a material having conductivity.

The vicinity of the magnetoresistance effect element 100 and the transistor Tr is covered with an insulating layer 90. The insulating layer 90 is an insulating layer that insulates between wirings of multilayer wirings and between elements. The insulating layer 90 may be formed of, for example, silicon oxide (SiOₓ), silicon nitride (SiNₓ), silicon carbide (SiC), chromium nitride (CrN), silicon carbonitride (SiCN), silicon oxynitride (SiON), aluminum oxide (Al₂O₃), zirconium oxide (ZrOₓ), magnesium oxide (MgO), aluminum nitride (AlN), or the like.

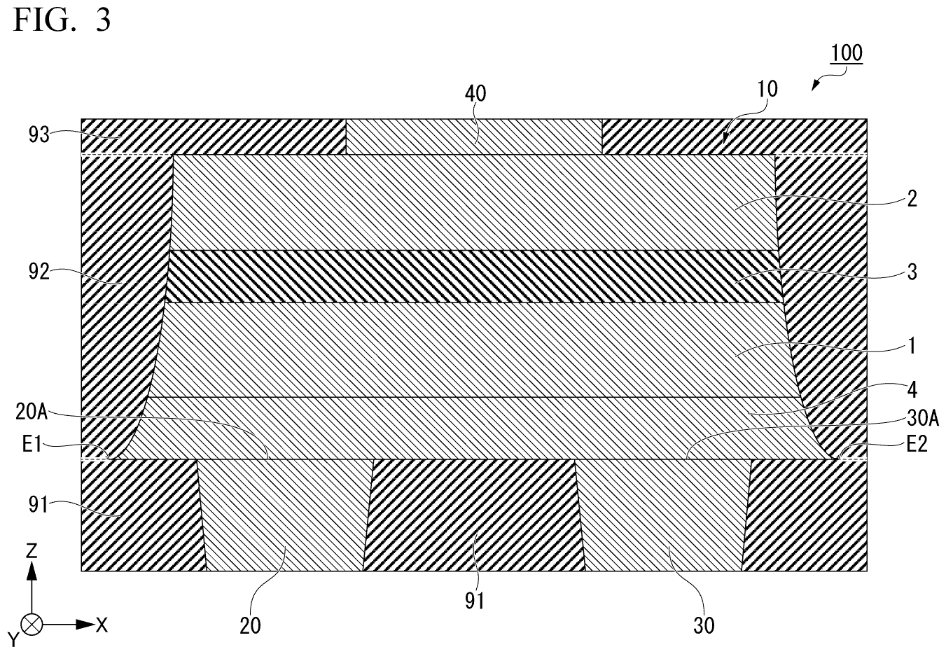

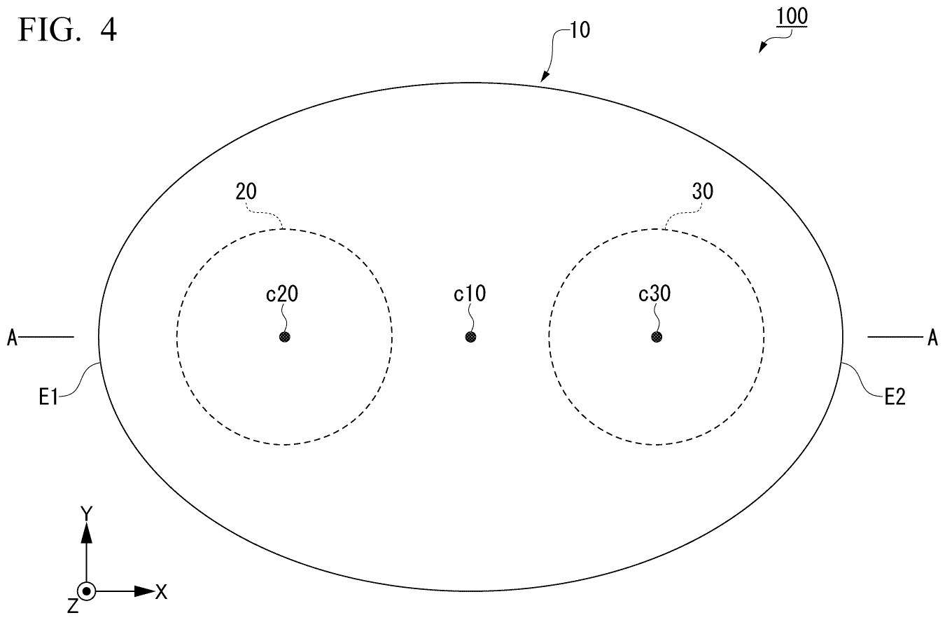

FIG. 3 is a cross-sectional view of the magnetoresistance effect element 100 according to the present embodiment. FIG. 4 is a plan view of the magnetoresistance effect element 100 according to the present embodiment. FIG. 3 is an XZ cross section taken along line A-A in FIG. 4. The line A-A is a line that follows a line connecting a shortest distance between a first wiring 20 and a second wiring 30. In FIG. 4, an electrode 40 and the insulating layer 90 are omitted.

The magnetoresistance effect element 100 includes, for example, a laminate 10, the first wiring 20, the second wiring 30, and the electrode 40. The vicinity of the magnetoresistance effect element 100 is covered with, for example, an insulating layer 91, an insulating layer 92, and an insulating layer 93. The insulating layer 91, the insulating layer 92, and the insulating layer 93 are parts of the insulating layer 90.

The magnetoresistance effect element 100 is a magnetic element utilizing a spin-orbit torque (SOT), and may be referred to as a spin-orbit torque magnetoresistance effect element, a spin-injection magnetoresistance effect element, or a spin-current magnetoresistance effect element.

The magnetoresistance effect element 100 is an element that records and stores data. The magnetoresistance effect element 100 records data using a resistance value of the laminate 10 in the Z direction. The resistance value of the laminate 10 in the Z direction changes when a write current is applied along a spin-orbit torque wiring 4 and spins are injected from the spin-orbit torque wiring 4 into a first ferromagnetic layer 1. The resistance value of the laminate 10 in the Z direction can be read when a read current is applied to the laminate 10 in the Z direction.

The laminate 10 includes the first ferromagnetic layer 1, a second ferromagnetic layer 2, a nonmagnetic layer 3, and the spin-orbit torque wiring 4. The laminate 10 may have the electrode 40 that connects the read line RL and the second ferromagnetic layer 2. For example, in the laminate 10, the spin-orbit torque wiring 4, the first ferromagnetic layer 1, the nonmagnetic layer 3, and the second ferromagnetic layer 2 are laminated in that order from a side closer to the substrate Sub.

The resistance value of the laminate 10 in the Z direction changes when spins are injected from the spin-orbit torque wiring 4 into the first ferromagnetic layer 1. The resistance value of the laminate 10 in the Z direction changes according to a change in relative angle between magnetizations of the first ferromagnetic layer 1 and the second ferromagnetic layer 2 sandwiching the nonmagnetic layer 3.

A shape of the laminate 10 in a plan view from the Z direction is, for example, circular, elliptical, or quadrangular. A side surface of the laminate 10 may be, for example, continuous in the Z direction and inclined with respect to the Z direction. The side surface being continuous in the Z direction means that there are no large steps at interfaces between layers, and side surfaces of the layers form a single surface. For example, in a cross section of the laminate 10 taken along the XZ plane, if an inclination of a tangent drawn along the side surface is constant or an inclination of the tangent line changes continuously, the side surface can be said to be continuous.

An element length in a plan view of the laminate 10 from the Z direction is, for example, 60 nm or less. If a shape of the laminate 10 in a plan view is a circle, the element length is a diameter of the laminate 10. If a shape of the laminate 10 in a plan view is other than a circle, the element length is a major axis diameter of the laminate 10.

The spin-orbit torque wiring 4 generates a spin current due to a spin Hall effect when a current flows therethrough, and injects the spins into the first ferromagnetic layer 1. The spin-orbit torque wiring 4 applies, for example, a spin-orbit torque (SOT) in an amount sufficient to reverse the magnetization of the first ferromagnetic layer 1 to the magnetization of the first ferromagnetic layer 1.

The spin Hall effect is a phenomenon in which a spin current is induced in a direction orthogonal to a direction in which a current flows on the basis of a spin-orbit interaction when the current is caused to flow. The spin Hall effect is the same as a normal Hall effect in that a moving (migrating) direction of moving (migrating) charges (electrons) is bent. In the normal Hall effect, a moving direction of charged particles moving in a magnetic field is bent by a Lorentz force. On the other hand, in the spin Hall effect, a moving direction of the spin is bent due to only movement of electrons (due to only a flow of current) even though a magnetic field is not present.

For example, when a current flows through the spin-orbit torque wiring 4, a first spin polarized in one direction and a second spin polarized in a direction opposite to the first spin are respectively bent by the spin Hall effect in a direction orthogonal to the direction in which the current flows. For example, the first spin polarized in the −Y direction is bent from the X direction, which is a direction of travel, to the +Z direction, and a second spin polarized in the +Y direction is bent from the X direction, which is the direction of travel, to the −Z direction.

In a nonmagnetic material (a material that is not ferromagnetic), the number of electrons with the first spin and the number of electrons with the second spin generated by the spin Hall effect are the same. That is, the number of electrons of the first spin oriented in the +Z direction is equal to the number of electrons of the second spin oriented in the −Z direction. The first spin and the second spin flow in a direction to eliminate an uneven distribution of the spins. In the movement of the first spin and the second spin in the Z direction, the flow of charges cancels each other out, and therefore an amount of current becomes zero. A spin current without a current is particularly referred to as a pure spin current.

When a flow of electrons in the first spin is expressed as J_{↑}, a flow of electrons in the second spin is expressed as J_{↓}, and a spin current is expressed as J_{S}, J_{S}=J_{↑}−J_{↓} is defined. The spin current J_{S} is generated in the Z direction. The first spin is injected from the spin-orbit torque wiring 4 into the first ferromagnetic layer 1.

A thickness of the spin-orbit torque wiring 4 is, for example, 2 nm or more. The thickness of the spin-orbit torque wiring 4 may be, for example, 20 nm or less.

The spin-orbit torque wiring 4 includes any one of a metal, an alloy, an intermetallic compound, a metal boride, a metal carbide, a metal silicide, a metal phosphide, and a metal nitride which have a function of generating a spin current.

The spin-orbit torque wiring 4 contains any one selected from the group consisting of, for example, heavy metals having an atomic number of 39 or higher, metal oxides, metal nitrides, metal oxynitrides, and topological insulators. The spin-orbit torque wiring 4 may also contain a magnetic material.

The spin-orbit torque wiring 4 contains, for example, a nonmagnetic heavy metal as a main component. A heavy metal means a metal having a specific gravity equal to or higher than that of yttrium (Y). The nonmagnetic heavy metal is, for example, a nonmagnetic metal having a high atomic number such as the atomic number of 39 or higher having d electrons or f electrons in the outermost shell. A stronger spin-orbit interaction is generated in the nonmagnetic heavy metal than in other metals. The spin Hall effect is generated by the spin-orbit interaction, and spins are likely to be unevenly distributed in the spin-orbit torque wiring 4 and the spin current J_{S} is likely to be generated.

The first ferromagnetic layer 1 is, for example, in contact with the spin-orbit torque wiring 4 and is laminated on the spin-orbit torque wiring 4.

The first ferromagnetic layer 1 is between the spin-orbit torque wiring 4 and the nonmagnetic layer 3 in the Z direction. The first ferromagnetic layer 1 is closer to the spin-orbit torque wiring 4 than the second ferromagnetic layer 2. Spins are injected into the first ferromagnetic layer 1 from the spin-orbit torque wiring 4. Magnetization of the first ferromagnetic layer 1 receives a spin-orbit torque (SOT) due to the injected spins and an orientation direction thereof is changed. The first ferromagnetic layer 1 is sometimes referred to as a magnetization free layer.

The first ferromagnetic layer 1 contains a ferromagnetic material. The ferromagnetic material is, for example, a metal selected from the group consisting of Cr, Mn, Co, Fe, and Ni, an alloy containing one or more of these metals, an alloy containing these metals and at least one element of B, C, and N, or the like. The ferromagnetic material is, for example, Co—Fe, Co—Fe—B, Ni—Fe, a Co—Ho alloy, a Sm—Fe alloy, an Fe—Pt alloy, a Co—Pt alloy, or a CoCrPt alloy.

The first ferromagnetic layer 1 may contain a Heusler alloy. A Heusler alloy contains an intermetallic compound having a chemical composition of XYZ or X₂YZ. X indicates a transition metal element of the Co, Fe, Ni, or Cu group, or a noble metal element in the periodic table, Y indicates a transition metal of the Mn, V, Cr, or Ti group, or species of the X element, and Z indicates a typical element from Group III to Group V. The Heusler alloy is, for example, Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, or the like. The Heusler alloy has a high spin polarization.

The nonmagnetic layer 3 is sandwiched between the first ferromagnetic layer 1 and the second ferromagnetic layer 2 in the Z direction. The nonmagnetic layer 3 is laminated, for example, on the first ferromagnetic layer 1.

The nonmagnetic layer 3 contains a nonmagnetic material. When the nonmagnetic layer 3 is an insulator (in a case of a tunnel barrier layer), for example, Al₂O₃, SiO₂, MgO, MgAl₂O₄, and the like can be used for a material thereof. Also, in addition to these materials, a material in which a part of Al, Si, and Mg is substituted with Zn, Be, or the like can also be used as the nonmagnetic layer 3. Of these, MgO and MgAl₂O₄ are materials that can realize coherent tunneling. If the nonmagnetic layer 3 is a metal, Cu, Au, Ag, or the like can be used for a material thereof. Further, if the nonmagnetic layer 3 is a semiconductor, Si, Ge, CuInSe₂, CuGaSe₂, Cu(In, Ga)Se₂, or the like can be used for a material thereof.

The second ferromagnetic layer 2 is at a position further away from the spin-orbit torque wiring 4 with respect to the first ferromagnetic layer 1. An orientation direction of a magnetization of the second ferromagnetic layer 2 is less likely to change than that of a magnetization of the first ferromagnetic layer 1 when a predetermined external force is applied. The second ferromagnetic layer 2 is referred to as a magnetization fixed layer or a magnetization reference layer.

The second ferromagnetic layer 2 contains a ferromagnetic material. The same material as the first ferromagnetic layer 1 may be used for the second ferromagnetic layer 2.

The laminate 10 may include a layer other than the first ferromagnetic layer 1, the second ferromagnetic layer 2, the nonmagnetic layer 3, and the spin-orbit torque wiring. For example, the laminate 10 may have a cap layer on an uppermost surface.

The first wiring 20 is connected to the spin-orbit torque wiring 4 of the laminate 10. The first wiring 20 is electrically connected to, for example, the write line WL via the switching element SW1.

The first wiring 20 is formed of a material having conductivity. The first wiring 20 has superior conductivity to the spin-orbit torque wiring 4. Conductivity of an element constituting the first wiring 20 is higher than, for example, conductivity of an element constituting the spin-orbit torque wiring 4. The first wiring 20 is formed of, for example, Cu, Al, Ag, or the like.

The first wiring 20 has a first end surface 20A on a side close to the spin-orbit torque wiring 4. The first end surface 20A is connected to, for example, the spin-orbit torque wiring 4. The first end surface 20A is positioned further inward within the magnetoresistance effect element 100 than a first end E1 of the spin-orbit torque wiring 4 in the X direction. The first end surface 20A is closer to a center of the magnetoresistance effect element 100 in the X direction than the first end E1. The first end surface 20A may be positioned further inward within the magnetoresistance effect element 100 than a first end of the second ferromagnetic layer 2 in the X direction.

As illustrated in FIG. 4, the first end surface 20A may be encompassed within the spin-orbit torque wiring 4 in a plan view from the Z direction. The first end surface 20A may be encompassed within the second ferromagnetic layer 2 in a plan view from the Z direction. A part of the first end surface 20A may protrude in the Y direction from the laminate 10 in a plan view from the Z direction.

The second wiring 30 is connected to the spin-orbit torque wiring 4 of the laminate 10. The second wiring 30 is electrically connected to, for example, the common line CL via the switching element SW2.

The second wiring 30 is connected to the spin-orbit torque wiring 4 at a position different from that of the first wiring 20 in the X direction. As illustrated in FIG. 4, in a plan view from the Z direction, a center c20 of the first wiring 20 and a center c30 of the second wiring 30 are preferably positioned to sandwich a center c10 of the laminate 10 in the X direction.

The second wiring 30 is formed of a material having conductivity. The same material as the first wiring 20 may be used for the second wiring 30.

The second wiring 30 has a first end surface 30A on a side close to the spin-orbit torque wiring 4. The first end surface 30A is an example of a second end surface. The first end surface 30A is connected to, for example, the spin-orbit torque wiring 4. The first end surface 30A is positioned further inward within the magnetoresistance effect element 100 than a second end E2 of the spin-orbit torque wiring 4 in the X direction. The first end surface 30A is closer to the center of the magnetoresistance effect element 100 in the X direction than the second end E2. The first end surface 30A may be positioned further inward of the magnetoresistance effect element 100 than a second end of the second ferromagnetic layer 2 in the X direction.

As illustrated in FIG. 4, the first end surface 30A may be encompassed within the spin-orbit torque wiring 4 in a plan view from the Z direction. The first end surface 30A may be encompassed within the second ferromagnetic layer 2 in a plan view from the Z direction. A part of the first end surface 30A may protrude in the Y direction from the laminate 10 in a plan view from the Z direction.

The magnetoresistance effect element 100 can be fabricated by repeating lamination and processing of each layer. The lamination of each layer can be performed using a sputtering method, a chemical vapor deposition (CVD) method, an electron beam evaporation method (EB evaporation method), an atomic laser deposition (ALD) method, or the like. The processing of each layer can be performed using, for example, photolithography, or the like.

For example, after the insulating layer 91 is deposited, an opening is formed in the insulating layer 91. The opening is filled with a conductor to form the first wiring 20 and the second wiring 30. After surfaces of the insulating layer 91, the first wiring 20 and the second wiring 30 are subjected to chemical mechanical polishing (CMP), the spin-orbit torque wiring 4, the first ferromagnetic layer 1, the nonmagnetic layer 3, and the second ferromagnetic layer 2 are laminated in that order and processed into a predetermined shape, thereby obtaining the laminate 10. A periphery of the laminate 10 is then covered with the insulating layer 92. The insulating layer 92 is an example of a sidewall insulating layer. Then, after surfaces of the laminate 10 and the insulating layer 92 are subjected to chemical mechanical polishing (CMP), the electrode 40 is formed, thereby obtaining the magnetoresistance effect element 100.

In the magnetoresistance effect element 100 according to the first embodiment, the first wiring 20 is inward of the first end E1 of the spin-orbit torque wiring 4. Therefore, even if a write current is caused to flow between the first wiring 20 and the second wiring 30, a flow of the write current from the first end E1 along the side surface of the laminate 10 can be suppressed. Electric field concentration is likely to occur at edges and interfaces, and a current is likely to concentrate there. Localized current concentration causes migration of elements. Migration of elements causes a decrease in stability of magnetization of the first ferromagnetic layer 1, thereby decreasing an MR ratio of the magnetoresistance effect element 100. The magnetoresistance effect element 100 according to the first embodiment can suppress localized current concentration and can operate stably.

### Second Embodiment

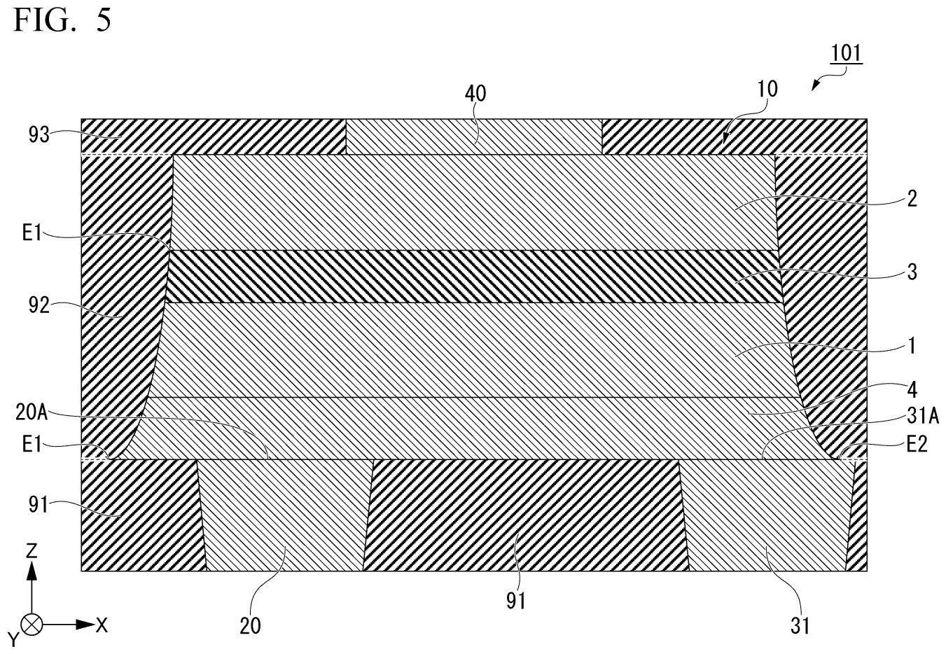

FIG. 5 is a cross-sectional view of a magnetoresistance effect element 101 according to a second embodiment. The magnetoresistance effect element 101 according to the second embodiment can be replaced with the magnetoresistance effect element 100 according to the first embodiment. The magnetoresistance effect element 101 according to the second embodiment differs from the magnetoresistance effect element 100 according to the first embodiment in position of a second wiring 31.

The second wiring 31 is similar to the second wiring 30 except for a connection position to a spin-orbit torque wiring 4.

The second wiring 31 is connected to the spin-orbit torque wiring 4 of a laminate 10. The second wiring 31 has a first end surface 31A on a side close to the spin-orbit torque wiring 4. The first end surface 31A is an example of a second end surface.

A part of the first end surface 31A is positioned on an outer side of the magnetoresistance effect element 101 with respect to a second end E2. In a plan view from the Z direction, a part of the first end surface 31A protrudes from the laminate 10. An end part of the first end surface 31A in the X direction is, for example, on an outer side of the magnetoresistance effect element 101 with respect to the second end E2.

In the magnetoresistance effect element 101 according to the second embodiment, a first wiring 20 is inward of a first end E1 of the spin-orbit torque wiring 4. Therefore, the magnetoresistance effect element 101 according to the second embodiment achieves the same effects as the magnetoresistance effect element 100 according to the first embodiment.

Also, a step is likely to occur at an interface between an insulating layer 91 and the first wiring 20 or the second wiring 31. The step causes a decrease in flatness of the laminate 10 and may decrease magnetization stability of the first ferromagnetic layer 1 and the second ferromagnetic layer 2. When a proportion in which the laminate 10 is laminated is reduced at an interface between the insulating layer 91 and the second wiring 31, reliability of the magnetoresistance effect element 101 is increased.

### Third Embodiment

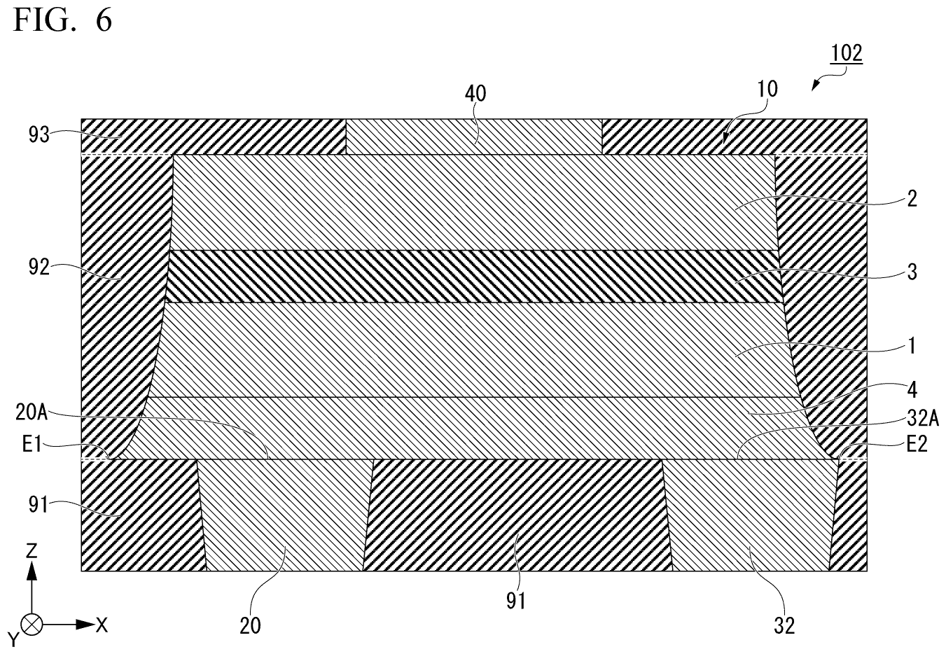

FIG. 6 is a cross-sectional view of a magnetoresistance effect element 102 according to a third embodiment. The magnetoresistance effect element 102 according to the third embodiment can be replaced with the magnetoresistance effect element 100 according to the first embodiment. The magnetoresistance effect element 102 according to the third embodiment differs from the magnetoresistance effect element 100 according to the first embodiment in position of a second wiring 32.

The second wiring 32 is similar to the second wiring 30 except for a connection position to a spin-orbit torque wiring 4.

The second wiring 32 is connected to the spin-orbit torque wiring 4 of a laminate 10. The second wiring 32 has a first end surface 32A on a side close to the spin-orbit torque wiring 4. The first end surface 32A is an example of a second end surface.

An end part of the first end surface 32A in the X direction coincides with a second end E2 of the spin-orbit torque wiring 4. A part of an outer circumference of the first end surface 32A is inscribed in the spin-orbit torque wiring 4.

In the magnetoresistance effect element 102 according to the third embodiment, a first wiring 20 is inward of a first end E1 of the spin-orbit torque wiring 4. Therefore, the magnetoresistance effect element 102 according to the third embodiment achieves the same effects as the magnetoresistance effect element 100 according to the first embodiment.

Also, when the second end E2 coincides with a part of the first end surface 32A, a contact area between an insulating layer 91 and an insulating layer 92 becomes larger. As a result, adhesion between a first layer, in which the first wiring 20 and the second wiring 30 are present, and a second layer, in which the laminate 10 is present, is increased, and peeling at an interface between them can be suppressed.

### Fourth Embodiment

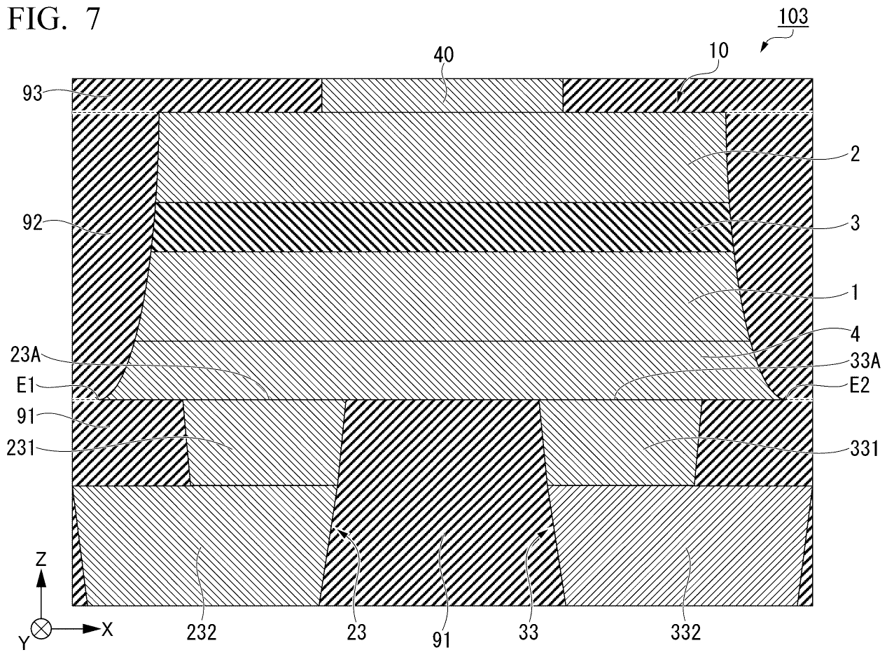

FIG. 7 is a cross-sectional view of a magnetoresistance effect element 103 according to a fourth embodiment. The magnetoresistance effect element 103 according to the fourth embodiment can be replaced with the magnetoresistance effect element 100 according to the first embodiment. The magnetoresistance effect element 103 according to the fourth embodiment differs from the magnetoresistance effect element 100 according to the first embodiment in shapes of a first wiring 23 and a second wiring 33.

The first wiring 23 has a first columnar body 231 and a second columnar body 232. The first columnar body 231 is in contact with a spin-orbit torque wiring 4. The second columnar body 232 is in contact with the first columnar body 231. There is a step between the first columnar body 231 and the second columnar body 232.

The first wiring 23 is similar to the first wiring 20 except that it is formed of a plurality of columnar bodies. The first wiring 23 has a first end surface 23A on a side close to the spin-orbit torque wiring 4. The first end surface 23A is an end surface of the first columnar body 231. The first end surface 23A is positioned further inward within the magnetoresistance effect element 103 than the first end E1.

The second wiring 33 has a first columnar body 331 and a second columnar body 332. The first columnar body 331 is in contact with the spin-orbit torque wiring 4. The second columnar body 332 is in contact with the first columnar body 331. There is a step between the first columnar body 331 and the second columnar body 332. The second wiring 33 is similar to the second wiring 30 except that it is formed of a plurality of columnar bodies.

The second wiring 33 is similar to the second wiring 30 except that it is formed of a plurality of columnar bodies. The second wiring 33 has a first end surface 33A on a side close to the spin-orbit torque wiring 4. The first end surface 33A is an end surface of the first columnar body 331. The first end surface 33A is an example of a second end surface. The first end surface 33A is positioned further inward within the magnetoresistance effect element 103 than the second end E2. An end part of the first end surface 33A may coincide with the second end E2, or may be on an outer side of the second end E2.

Here, an example in which the first wiring 23 and the second wiring 33 are each formed of two columnar bodies has been illustrated, but the number of columnar bodies constituting them is not limited. Also, an example in which the first wiring 23 and the second wiring 33 are each formed of a plurality of columnar bodies has been illustrated, but only one of them may be formed of a plurality of columnar bodies.

In the magnetoresistance effect element 103 according to the fourth embodiment, the first end surface 23A is inward of the first end E1 of the spin-orbit torque wiring 4. Therefore, the magnetoresistance effect element 103 according to the fourth embodiment achieves the same effects as the magnetoresistance effect element 100 according to the first embodiment.

Also, an element diameter of a laminate 10 of the magnetoresistance effect element 103 is often smaller than a size of a switching element such as a transistor Tr. When the first wiring 23 and the second wiring 33 are formed of a plurality of columnar bodies, a difference in size between them can be easily adjusted by the first wiring 23 and the second wiring 33.

### Fifth Embodiment

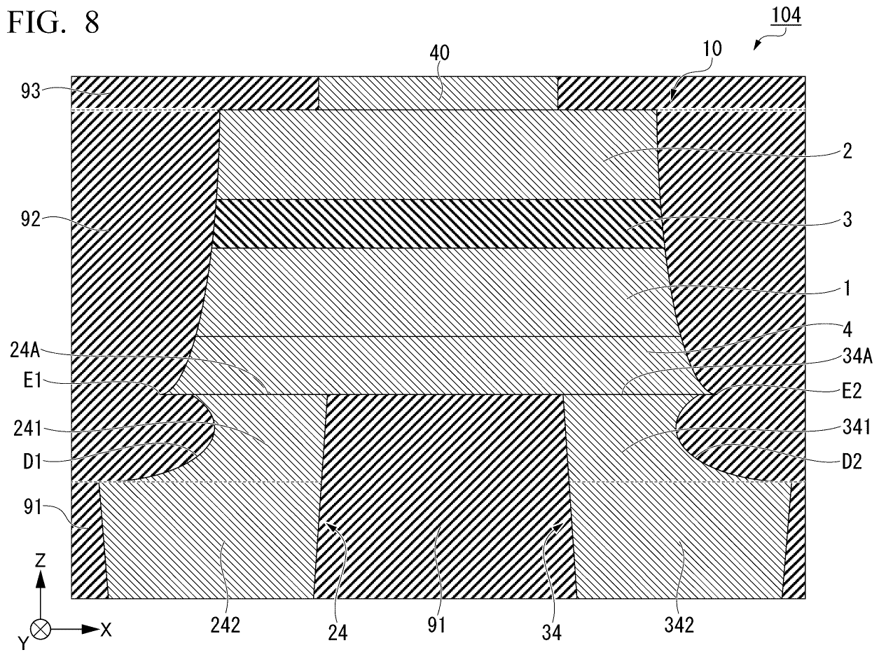

FIG. 8 is a cross-sectional view of a magnetoresistance effect element 104 according to a fifth embodiment. The magnetoresistance effect element 104 according to the fifth embodiment can be replaced with the magnetoresistance effect element 100 according to the first embodiment. The magnetoresistance effect element 104 according to the fifth embodiment differs from the magnetoresistance effect element 100 according to the first embodiment in shapes of a first wiring 24 and a second wiring 34.

The first wiring 24 has a connection portion 241 and a main body portion 242. The connection portion 241 is in contact with a spin-orbit torque wiring 4. The main body portion 242 is in contact with the connection portion 241.

A part of a side surface of the connection portion 241 is recessed inward of the magnetoresistance effect element 104. The connection portion 241 has a recessed portion D1. In an XZ cross section, the recessed portion D1 is on an outer side surface of the first wiring 24. The outer side surface of the first wiring 24 in the XZ cross section is recessed toward the inside.

The recessed portion D1 can be fabricated by the following procedure. First, an opening formed in an insulating layer 91 is filled with a conductor to form a columnar body that will serve as the first wiring 24. Then, an outer portion of the columnar body is irradiated with an ion beam from an oblique direction. The ion beam removes a part of the columnar body to form the recessed portion D1. When a periphery of a laminate 10 is covered with an insulating layer 92, a periphery of the recessed portion D1 is also covered with the insulating layer 92 at the same time. A part of the insulating layer 92 wraps around to a lower side of the laminate 10, thereby further suppressing interfacial peeling.

The first wiring 24 is similar to the first wiring 20 except for a shape. The first wiring 24 has a first end surface 24A on a side close to the spin-orbit torque wiring 4. The first end surface 24A is positioned further inward within the magnetoresistance effect element 104 than a first end E1.

The second wiring 34 has a connection portion 341 and a main body portion 342. The connection portion 341 is in contact with the spin-orbit torque wiring 4. The main body portion 342 is in contact with the connection portion 341.

A part of a side surface of the connection portion 341 is recessed inward of the magnetoresistance effect element 104. The connection portion 341 has a recessed portion D2. In the XZ cross section, the recessed portion D2 is on an outer side surface of the second wiring 34. The outer side surface of the second wiring 34 in the XZ cross section is recessed toward the inside. The recessed portion D2 can be fabricated by the same procedure as the recessed portion D1.

The second wiring 34 is similar to the second wiring 30 except for a shape. The second wiring 34 has a first end surface 34A on a side close to the spin-orbit torque wiring 4. The first end surface 34A is an example of a second end surface. The first end surface 34A is positioned further inward within the magnetoresistance effect element 104 than a second end E2. An end part of the first end surface 34A may coincide with the second end E2, or may be on an outer side of the second end E2.

Here, an example in which the first wiring 24 has the recessed portion D1 and the second wiring 34 has the recessed portion D2 has been illustrated, but only one of them may have the recessed portion D1 or the recessed portion D2.

In the magnetoresistance effect element 104 according to the fifth embodiment, the first end surface 24A is inward of the first end E1 of the spin-orbit torque wiring 4. Therefore, the magnetoresistance effect element 104 according to the fifth embodiment achieves the same effects as the magnetoresistance effect element 100 according to the first embodiment.

Also, when the magnetoresistance effect element 104 has the recessed portion D1 and the recessed portion D2, a distance between wirings of adjacent magnetoresistance effect elements 104 can be reduced. When a gap between adjacent magnetoresistance effect elements 104 is reduced, an integration density of the magnetic memory 200 is increased.

### Sixth Embodiment

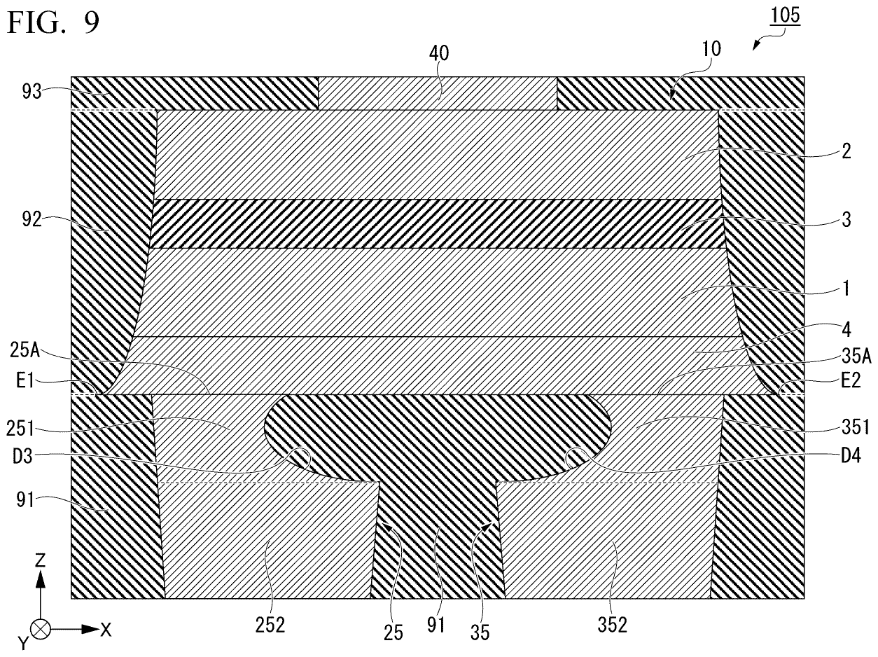

FIG. 9 is a cross-sectional view of a magnetoresistance effect element 105 according to a sixth embodiment. The magnetoresistance effect element 105 according to the sixth embodiment can be replaced with the magnetoresistance effect element 100 according to the first embodiment. The magnetoresistance effect element 105 according to the sixth embodiment differs from the magnetoresistance effect element 100 according to the first embodiment in shapes of a first wiring 25 and a second wiring 35.

The first wiring 25 has a connection portion 251 and a main body portion 252. The connection portion 251 is in contact with a spin-orbit torque wiring 4. The main body portion 252 is in contact with the connection portion 251.

A part of a side surface of the connection portion 251 is recessed outward of the magnetoresistance effect element 105. The connection portion 251 has a recessed portion D3. In an XZ cross section, the recessed portion D3 is on an inner side surface of the first wiring 25. The inner side surface of the first wiring 25 in the XZ cross section is recessed toward the outside of the magnetoresistance effect element 105.

The recessed portion D3 can be fabricated by the following procedure. First, an opening formed in an insulating layer 91 is filled with a conductor to form a columnar body that will serve as the first wiring 25. Then, an inner portion of the columnar body is irradiated with an ion beam from an oblique direction. The ion beam removes a part of the columnar body to form the recessed portion D3. The recessed portion D3 is filled with the insulating layer 91.

The first wiring 25 is similar to the first wiring 20 except for a shape. The first wiring 25 has a first end surface 25A on a side close to the spin-orbit torque wiring 4. The first end surface 25A is positioned further inward within the magnetoresistance effect element 105 than a first end E1.

The second wiring 35 has a connection portion 351 and a main body portion 352. The connection portion 351 is in contact with the spin-orbit torque wiring 4. The main body portion 352 is in contact with the connection portion 351.

A part of a side surface of the connection portion 351 is recessed outward of the magnetoresistance effect element 105. The connection portion 351 has a recessed portion D4. In the XZ cross section, the recessed portion D4 is on an inner side surface of the second wiring 35. The inner side surface of the second wiring 35 in the XZ cross section is recessed toward the outside the magnetoresistance effect element 105. The recessed portion D4 can be fabricated by the same procedure as the recessed portion D3.

The second wiring 35 is similar to the second wiring 30 except for a shape. The second wiring 35 has a first end surface 35A on a side close to the spin-orbit torque wiring 4. The first end surface 35A is an example of a second end surface. The first end surface 35A is positioned further inward within the magnetoresistance effect element 104 than a second end E2. An end part of the first end surface 35A may coincide with the second end E2, or may be on an outer side of the second end E2.

Here, an example in which the first wiring 25 has the recessed portion D3 and the second wiring 35 has the recessed portion D4 has been illustrated, but only one of them may have the recessed portion D3 or the recessed portion D4.

In the magnetoresistance effect element 105 according to the sixth embodiment, the first end surface 25A is inward of the first end E1 of the spin-orbit torque wiring 4. Therefore, the magnetoresistance effect element 105 according to the sixth embodiment achieves the same effects as the magnetoresistance effect element 100 according to the first embodiment.

Also, when the magnetoresistance effect element 105 has the recessed portion D3 and the recessed portion D4, a distance along which a write current flows through the spin-orbit torque wiring 4 increases, and an amount of spin injected into the first ferromagnetic layer 1 can be increased.

### Seventh Embodiment

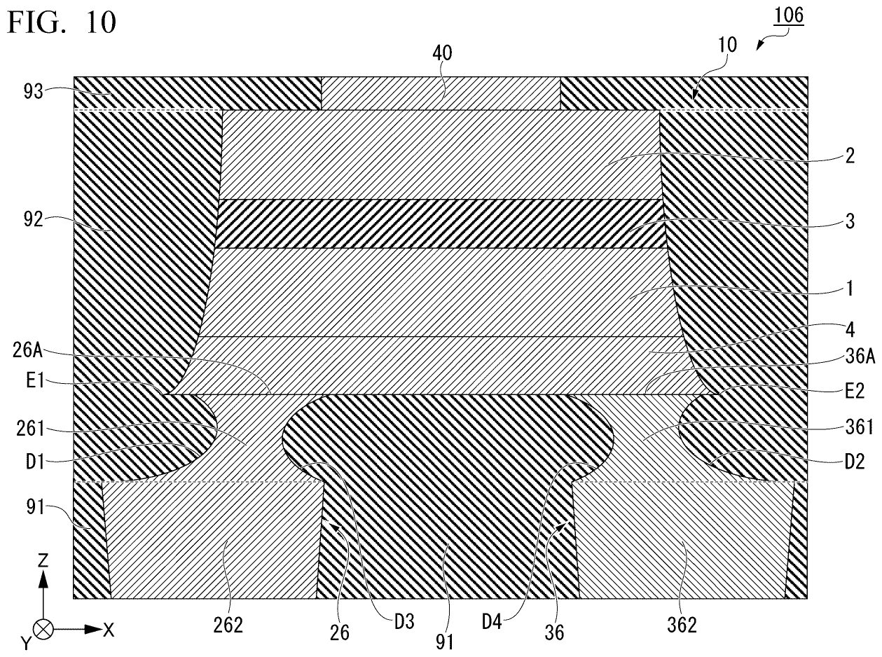

FIG. 10 is a cross-sectional view of a magnetoresistance effect element 106 according to a seventh embodiment. The magnetoresistance effect element 106 according to the seventh embodiment can be replaced with the magnetoresistance effect element 100 according to the first embodiment. The magnetoresistance effect element 106 according to the seventh embodiment differs from the magnetoresistance effect element 100 according to the first embodiment in shapes of a first wiring 26 and a second wiring 36.

The first wiring 26 has a connection portion 261 and a main body portion 262. The connection portion 261 is in contact with a spin-orbit torque wiring 4. The main body portion 262 is in contact with the connection portion 261.

A side surface of the connection portion 261 has a recessed portion D1 recessed inward and a recessed portion D3 recessed outward. The recessed portion D1 is the same as that of the magnetoresistance effect element 104 according to the fifth embodiment. The recessed portion D3 is the same as that of the magnetoresistance effect element 105 according to the sixth embodiment.

The first wiring 26 is similar to the first wiring 20 except for a shape. The first wiring 26 has a first end surface 26A on a side close to the spin-orbit torque wiring 4. The first end surface 26A is positioned further inward within the magnetoresistance effect element 106 than a first end E1.

The second wiring 36 has a connection portion 361 and a main body portion 362. The connection portion 361 is in contact with the spin-orbit torque wiring 4. The main body portion 362 is in contact with the connection portion 361.

A side surface of the connection portion 361 has a recessed portion D2 recessed inward and a recessed portion D4 recessed outward. The recessed portion D2 is the same as that of the magnetoresistance effect element 104 according to the fifth embodiment. The recessed portion D4 is the same as that of the magnetoresistance effect element 105 according to the sixth embodiment.

The second wiring 36 is similar to the second wiring 30 except for a shape. The second wiring 36 has a first end surface 36A on a side close to the spin-orbit torque wiring 4. The first end surface 36A is an example of a second end surface. The first end surface 36A is positioned further inward within the magnetoresistance effect element 106 than a second end E2. An end part of the first end surface 36A may coincide with the second end E2, or may be on an outer side of the second end E2.

Here, an example in which the first wiring 26 has the recessed portion D1 and the recessed portion D3, and the second wiring 36 has the recessed portion D2 and the recessed portion D4 has been illustrated, but only one of them may have a recessed portion.

In the magnetoresistance effect element 106 according to the seventh embodiment, the first end surface 26A is inward of the first end E 1 of the spin-orbit torque wiring 4. Therefore, the magnetoresistance effect element 106 according to the seventh embodiment achieves the same effects as the magnetoresistance effect element 100 according to the first embodiment.

Also, since the magnetoresistance effect element 106 has the recessed portion D1, the recessed portion D2, the recessed portion D3, and the recessed portion D4, the same effects as those of the fifth and sixth embodiments are achieved.

### Eighth Embodiment

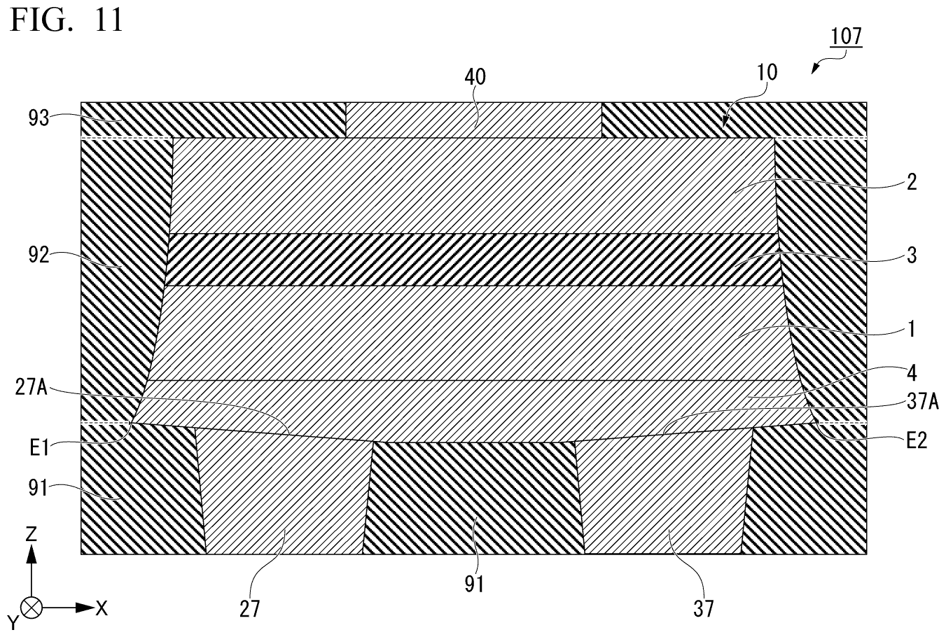

FIG. 11 is a cross-sectional view of a magnetoresistance effect element 107 according to an eighth embodiment. The magnetoresistance effect element 107 according to the eighth embodiment can be replaced with the magnetoresistance effect element 100 according to the first embodiment. The magnetoresistance effect element 107 according to the eighth embodiment differs from the magnetoresistance effect element 100 according to the first embodiment in shapes of a first wiring 27 and a second wiring 37.

The first wiring 27 is similar to the first wiring 20 except for a shape. The first wiring 27 has a first end surface 27A on a side close to a spin-orbit torque wiring 4. The first end surface 27A is positioned further inward within the magnetoresistance effect element 107 than a first end E1. The first end surface 27A is inclined with respect to the XY plane. The inclined surface may be curved. A part of a laminate 10 may be inclined with respect to the XY plane along the first end surface 27A.

The second wiring 37 is similar to the second wiring 30 except for a shape. The second wiring 37 has a first end surface 37A on a side close to the spin-orbit torque wiring 4. The first end surface 37A is positioned further inward within the magnetoresistance effect element 107 than a second end E2. An end part of the first end surface 37A may coincide with the second end E2 or may be on an outer side of the second end E2. The first end surface 37A is inclined with respect to the XY plane. The inclined surface may be curved. A part of the laminate 10 may be inclined with respect to the XY plane along the first end surface 37A.

Here, an example in which both the first end surface 27A and the first end surface 37A are inclined has been illustrated, but only one of them may be inclined.

In the magnetoresistance effect element 107 according to the eighth embodiment, the first end surface 27A is inward of the first end E1 of the spin-orbit torque wiring 4. Therefore, the magnetoresistance effect element 107 according to the eighth embodiment achieves the same effects as the magnetoresistance effect element 100 according to the first embodiment.

Also, since the first end surface 27A and the first end surface 37A are inclined, the magnetoresistance effect element 107 becomes more resistant to a stress applied in the X and Y directions, and interfacial peeling can be further suppressed.

### Ninth Embodiment

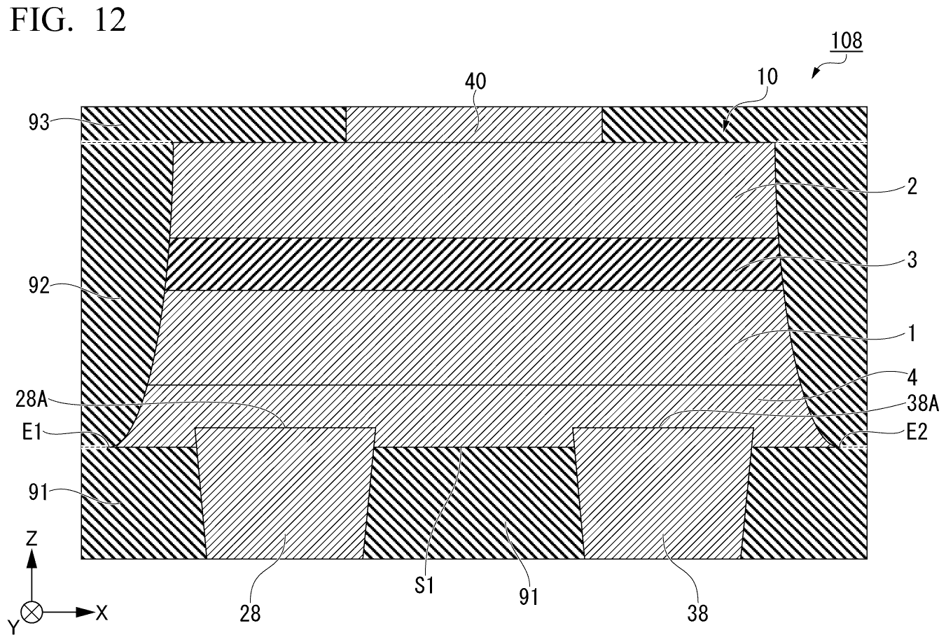

FIG. 12 is a cross-sectional view of a magnetoresistance effect element 108 according to a ninth embodiment. The magnetoresistance effect element 108 according to the ninth embodiment can be replaced with the magnetoresistance effect element 100 according to the first embodiment. The magnetoresistance effect element 108 according to the ninth embodiment differs from the magnetoresistance effect element 100 according to the first embodiment in shapes of a first wiring 28 and a second wiring 38.

The first wiring 28 is similar to the first wiring 20 except for a positional relationship. The first wiring 28 has a first end surface 28A on a side close to a spin-orbit torque wiring 4. The first end surface 28A is positioned further inward within the magnetoresistance effect element 108 than a first end E1.

A non-connection surface S1 of a first surface of the spin-orbit torque wiring 4 is positioned farther from a first ferromagnetic layer 1 than the first end surface 28A in a Z direction. The first surface of the spin-orbit torque wiring 4 is a surface on a side opposite to a surface of the spin-orbit torque wiring 4 in contact with the first ferromagnetic layer 1. The first end surface 28A and the non-connection surface S1 are at different height positions in the Z direction, and there is a step between the first end surface 28A and the non-connection surface S1. This step can be produced by controlling polishing conditions when an insulating layer 91 and one surface of the first wiring 28 are polished.

The second wiring 38 is similar to the second wiring 30 except for a positional relationship. The second wiring 38 has a first end surface 38A on a side close to the spin-orbit torque wiring 4. The first end surface 38A is positioned further inward within the magnetoresistance effect element 108 than a second end E2. An end part of the first end surface 38A may coincide with the second end E2 or may be on an outer side of the second end E2.

The non-connection surface S1 of the first surface of the spin-orbit torque wiring 4 is positioned farther from the first ferromagnetic layer 1 than the first end surface 38A in the Z direction. The first end surface 38A and the non-connection surface S1 are at different height positions in the Z direction, and there is a step between the first end surface 38A and the non-connection surface S1. This step can be produced by controlling polishing conditions when the insulating layer 91 and one surface of the second wiring 38 are polished.

In the magnetoresistance effect element 108 according to the ninth embodiment, the first wiring 28 is inward of the first end E1 of the spin-orbit torque wiring 4. Therefore, the magnetoresistance effect element 108 according to the ninth embodiment achieves the same effects as the magnetoresistance effect element 100 according to the first embodiment.

Also, since there are steps between the first end surface 28A and the first end surface 38A, and the non-connection surface S1, the magnetoresistance effect element 108 becomes more resistant to a stress applied in the X and Y directions, and interfacial peeling can be further suppressed.

### Tenth Embodiment

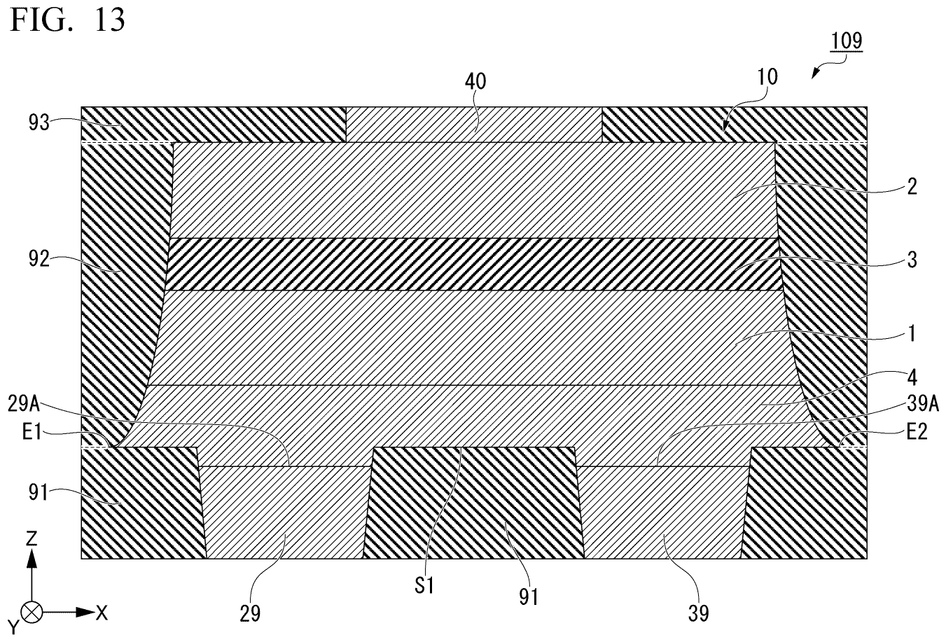

FIG. 13 is a cross-sectional view of a magnetoresistance effect element 109 according to a tenth embodiment. The magnetoresistance effect element 109 according to the tenth embodiment can be replaced with the magnetoresistance effect element 100 according to the first embodiment. The magnetoresistance effect element 109 according to the tenth embodiment differs from the magnetoresistance effect element 100 according to the first embodiment in shapes of a first wiring 29 and a second wiring 39.

The first wiring 29 is similar to the first wiring 20 except for a positional relationship. The first wiring 29 has a first end surface 29A on a side close to a spin-orbit torque wiring 4. The first end surface 29A is positioned further inward within the magnetoresistance effect element 109 than a first end E1.

A non-connection surface S1 of a first surface of the spin-orbit torque wiring 4 is closer to a first ferromagnetic layer 1 than the first end surface 29A in the Z direction. The first end surface 29A and the non-connection surface S1 are at different height positions in the Z direction, and there is a step between the first end surface 29A and the non-connection surface S1. This step can be produced by controlling polishing conditions when an insulating layer 91 and one surface of the first wiring 29 are polished.

The second wiring 39 is similar to the second wiring 30 except for a positional relationship. The second wiring 39 has a first end surface 39A on a side close to the spin-orbit torque wiring 4. The first end surface 39A is positioned further inward within the magnetoresistance effect element 109 than a second end E2. An end part of the first end surface 39A may coincide with the second end E2, or may be on an outer side of the second end E2.

The non-connection surface S1 of the first surface of the spin-orbit torque wiring 4 is closer to the first ferromagnetic layer 1 than the first end surface 39A in the Z direction. The first end surface 39A and the non-connection surface S1 are at different height positions in the Z direction, and there is a step between the first end surface 39A and the non-connection surface S1. This step can be produced by controlling polishing conditions when the insulating layer 91 and one surface of the second wiring 39 are polished.

In the magnetoresistance effect element 109 according to the tenth embodiment, the first wiring 29 is inward of the first end E1 of the spin-orbit torque wiring 4. Therefore, the magnetoresistance effect element 109 according to the tenth embodiment achieves the same effects as the magnetoresistance effect element 100 according to the first embodiment.

Also, since there are steps between the first end surface 29A and the first end surface 39A, and the non-connection surface S1, the magnetoresistance effect element 109 becomes more resistant to a stress applied in the X and Y directions, and interfacial peeling can be further suppressed.

Several embodiments have been exemplified as described above to describe specific structures of the present disclosure. However, the present disclosure is not limited to these specific examples, and various modifications can be made within the scope of achieving the objective.

For example, the characteristic configurations of the magnetoresistance effect elements according to the first to tenth embodiments may be incorporated into the other embodiments. Also, for example, in the magnetoresistance effect elements according to the first to tenth embodiments, a top-pin structure in which the second ferromagnetic layer 2 serving as a magnetization fixed layer is at a position away from the first ferromagnetic layer 1 has been exemplified, but a bottom-pin structure in which the second ferromagnetic layer 2 is closer to the substrate Sub than the first ferromagnetic layer 1 may also be used. In the bottom-pin structure, a lamination order of the laminate 10 is opposite to that of the top-pin structure, and the first wiring and the second wiring are connected to the laminate from above.

### REFERENCE SIGNS LIST

1 First ferromagnetic layer
2 Second ferromagnetic layer
3 Nonmagnetic layer
4 Spin-orbit torque wiring
10 Laminate
20, 23, 24, 25, 26, 27, 28, 29 First wiring
20A, 23A, 24A, 25A, 26A, 27A, 28A, 29A First end surface
30, 31, 32, 33, 34, 35, 36, 37, 38, 39 Second wiring
30A, 31A, 32A, 33A, 34A, 35A, 36A, 37A, 38A, 39A First end surface
40 Electrode
90, 91, 92, 93 Insulating layer
100, 101, 102, 103, 104, 105, 106, 107, 108, 109 Magnetoresistance effect element
200 Magnetic memory
231, 331 First columnar body
232, 332 Second columnar body
241, 251, 261, 341, 351, 361 Connection portion
242, 252, 262, 342, 352, 362 Main body portion
c10, c20, c30 Center
D1, D2, D3, D4 Recessed portion
E1 First end
E2 Second end
S1 Non-connection surface

What is claimed is:

1. A magnetoresistance effect element comprising a laminate, a first wiring, and a second wiring, wherein
the laminate includes a spin-orbit torque wiring, a first ferromagnetic layer, a nonmagnetic layer, and a second ferromagnetic layer,
a side surface of the laminate is a continuous inclined surface,
the first ferromagnetic layer is between the spin-orbit torque wiring and the nonmagnetic layer in a lamination direction of the laminate,
the nonmagnetic layer is between the first ferromagnetic layer and the second ferromagnetic layer in the lamination direction of the laminate,
the first wiring is connected to the spin-orbit torque wiring,
the second wiring is connected to the spin-orbit torque wiring at a position different from that of the first wiring in a first direction, and
a first end surface of the first wiring on a side close to the spin-orbit torque wiring is inward of a first end of the spin-orbit torque wiring in the first direction.

2. The magnetoresistance effect element according to claim 1, wherein a part of a second end surface of the second wiring on a side close to the spin-orbit torque wiring is outward of a second end of the spin-orbit torque wiring in the first direction.

3. The magnetoresistance effect element according to claim 1, wherein an end part in the first direction of a second end surface of the second wiring on a side close to the spin-orbit torque wiring coincides with a second end of the spin-orbit torque wiring in the first direction.

4. The magnetoresistance effect element according to claim 1, wherein a second end surface of the second wiring on a side close to the spin-orbit torque wiring is inward of a second end of the spin-orbit torque wiring in the first direction.

5. The magnetoresistance effect element according to claim 1, wherein the first end surface is encompassed within the second ferromagnetic layer in a plan view from the lamination direction.

6. The magnetoresistance effect element according to claim 1, wherein a center of the laminate is sandwiched between a center of the first wiring and a center of the second wiring in the first direction in a plan view from the lamination direction.

7. The magnetoresistance effect element according to claim 1, wherein an element diameter of the laminate is 60 nm or less when viewed from the lamination direction.

8. The magnetoresistance effect element according to claim 1, wherein
the first wiring includes a first columnar body and a second columnar body,
the first columnar body is in contact with the spin-orbit torque wiring, and
the second columnar body is in contact with the first columnar body.

9. The magnetoresistance effect element according to claim 1, wherein
the first wiring has a connection portion which is in contact with the spin-orbit torque wiring, and
a part of a side surface of the connection portion is recessed toward the inside of the magnetoresistance effect element.

10. The magnetoresistance effect element according to claim 1, wherein
the first wiring has a connection portion which is in contact with the spin-orbit torque wiring, and
a part of a side surface of the connection portion is recessed toward the outside of the magnetoresistance effect element.

11. The magnetoresistance effect element according to claim 1, wherein
the first wiring has a connection portion which is in contact with the spin-orbit torque wiring, and
a side surface of the connection portion has a first recessed portion recessed toward the inside of the magnetoresistance effect element and a second recessed portion recessed toward the outside of the magnetoresistance effect element.

12. The magnetoresistance effect element according to claim 9, further comprising a sidewall insulating layer surrounding a periphery of the laminate, wherein
a part of the sidewall insulating layer covers a recessed portion of the connection portion.

13. The magnetoresistance effect element according to claim 1, wherein at least a part of the first end surface is inclined with respect to a plane orthogonal to the lamination direction.

14. The magnetoresistance effect element according to claim 1, wherein, of a first surface facing a surface of the spin-orbit torque wiring in contact with the first ferromagnetic layer, a non-connection surface which is not in contact with the first wiring and the second wiring is positioned farther from the first ferromagnetic layer than the first end surface in the lamination direction.

15. The magnetoresistance effect element according to claim 1, wherein, of a first surface facing a surface of the spin-orbit torque wiring in contact with the first ferromagnetic layer, a non-connection surface which is not in contact with the first wiring and the second wiring is closer to the first ferromagnetic layer than the first end surface in the lamination direction.

16. A magnetic memory including a magnetoresistance effect element according to claim 1.
